(19) United States
(12) Patent Application Publication
(10) Pub. No.: US 2019/0166717 A1
(43) Pub. Date: May 30, 2019

(54) METHOD AND SYSTEM FOR CARBON DIOXIDE COMPRESSED GAS ELECTRONIC COOLING

(71) Applicant: BAE SYSTEMS Information and Electronic Systems Integration Inc., Nashua, NH (US)

(72) Inventors: Thomas M. GASS, Barrington, NH (US); Edward THOMAN, JR., Merrimack, NH (US)

(21) Appl. No.: 15/823,997

(22) Filed: Nov. 28, 2017

(51) Int. Cl. H05K 7/20; F25B 9/00; F25B 9/06; G01K 3/00

(52) U.S. Cl. CPC H05K 7/20154; G01K 3/005; F25B 9/06; F25B 9/008

(57) ABSTRACT

A system and method for cooling electronics with compressed gas cylinders. A small, lightweight, scalable cooling system provides portability and cooling for electronic components in remote areas. In some cases one or more compressed gas cylinders are used with a metering valve and a temperature sensor to release gas into an expansion chamber or channels in thermal contact with a heat sink that is in thermal contact with an electric component.

### FIELD OF THE DISCLOSURE

The present disclosure relates to the cooling of electronics and more particularly to the use of compressed gas to cool electronics in the field.

### BACKGROUND OF THE DISCLOSURE

Active cooling methods for electronic assemblies typically include liquid cooling through a conductive cold plate, forced convection through the use of fans or supplied air systems, or a purely conductive method of heatsinking the assembly to a large thermal mass. In certain applications, the above mitigation strategies may not meet the full extent of the environmental requirements, or may not be practical to implement for a variety of reasons. In some cases, the cooling requirements are only required for certain time intervals such that complex or expensive cooling infrastructures are not economical.

### SUMMARY OF THE DISCLOSURE

An aspect of the present disclosure is a compressed gas cooling system, comprising: at least one compressed gas cartridge having a threaded end; a metering valve connected to the at least one compressed gas cartridge; a controller for actuating the metering valve in response to temperature threshold information from at least one temperature sensor; an expansion chamber in fluid connection with the metering valve; and a heat sink in thermal contact with an electronic component.

One embodiment of the compressed gas electronic cooling system is wherein the compressed gas cartridge is carbon dioxide. In some cases, the at least one compressed gas cartridge is two cartridges.

In certain embodiments, the heat sink comprises aluminum. In some cases, a threaded interface acts as the connection for the at least one compressed gas cartridge.

In another embodiment of the compressed gas electronic cooling system, the system further comprises a control valve actuated via temperature sensing circuitry.

Another aspect of the present disclosure is a method of cooling electronics, comprising: providing at least one compressed gas cartridge in communication with an metering valve; sensing, with a temperature sensor, the temperature of at least one electronic component; providing an expansion chamber in connection with the metering valve and in thermal contact with a heat sink which is in thermal contact with the electronic component; determining that a threshold temperature of the heat sink has been met; actuating the metering valve, via a controller, in response to the temperature threshold detected by a temperature sensor; releasing compressed gas from the compressed gas cartridge into the expansion chamber for a period of time; transferring, via conduction, cooler temperature from the expansion chamber to the heat sink; transferring, via conduction, cooler temperature from the heat sink to the electronic component until a temperature set point for the heat sink is reached; closing the metering valve until the temperature threshold is met.

One embodiment of the method of electronic cooling is wherein the compressed gas cartridge is carbon dioxide. In some cases, the at least one compressed gas cartridge is two cartridges.

Another embodiment of the method of electronic cooling is wherein the temperature threshold is 70° C. In some cases, the temperature set point is 0° C. In certain embodiments, the period of time is between 10 minutes and 15 minutes.

In certain embodiments, the heat sink comprises aluminum. In some cases, a threaded interface acts as the connection for the at least one compressed gas cartridge.

Yet another embodiment of the method of electronic cooling further comprises a control valve actuated via temperature sensing circuitry.

Yet another aspect of the present disclosure is a compressed gas cooling system, comprising: at least one compressed gas cartridge having a threaded end; a metering valve connected to the at least one compressed gas cartridge via a threaded interface; a controller for actuating the metering valve in response to temperature threshold information from at least one temperature sensor; and an aluminum heat sink having internal coolant passages that routes exhausted compressed gas throughout the system in thermal contact with an electronic component.

One embodiment of the compressed gas electronic cooling system is wherein the compressed gas cartridge is carbon dioxide. In some cases, the at least one compressed gas cartridge is two cartridges.

Certain embodiments of the compressed gas electronic cooling system further comprise a control valve actuated via temperature sensing circuitry.

These aspects of the disclosure are not meant to be exclusive and other features, aspects, and advantages of the present disclosure will be readily apparent to those of ordinary skill in the art when read in conjunction with the following description, appended claims, and accompanying drawings.

### BRIEF DESCRIPTION OF THE DRAWINGS

The foregoing and other objects, features, and advantages of the disclosure will be apparent from the following description of particular embodiments of the disclosure, as illustrated in the accompanying drawings in which like reference characters refer to the same parts throughout the different views. The drawings are not necessarily to scale, emphasis instead being placed upon illustrating the principles of the disclosure.

FIG. 1A is a diagram of one embodiment of the system of the present disclosure.

FIG. 1B is a diagrammatic view of one embodiment of the system of the present disclosure.

FIG. 2 is a diagram of one embodiment of the method of the present disclosure.

FIG. 3 is a flowchart of one embodiment of the method of the present disclosure.

### DETAILED DESCRIPTION OF THE DISCLOSURE

The proposed electronic cooling system integrates readily available pressurized CO₂, a cooling plate that takes advantage of the CO₂ as a cooling media, and a temperature controlled valve system that meters the release of the compressed gas. This system is self-contained, scalable based on heat loads, and can be designed to fit within a small volume. In one example it provides a cost effective technique to provide temporary cooling.

Certain embodiments of the present disclosure provide a scaleable, compact, active cooling mechanism for electronics. This active electronic cooling mechanism is useful for platforms that do not have internal cooling capability. It can also be used to extend the cooling capability of air-cooled or conduction cooled systems.

In one embodiment, the system uses disposable carbon dioxide (CO₂) canisters. These canisters are typically utilized on recreational products (e.g., bicycle tire inflators, air rifles, etc.) as propellants. In certain embodiments, the cartridges are cylindrical and are about four inches long and about 0.75 inches in diameter. In some cases, compressed gases with similar material properties could be used, but the availability and cost of CO₂ canisters makes them a good choice.

One embodiment of the system of the present disclosure uses the controlled release of compressed CO₂ canisters as a mechanism to actively cool a heatsink. In some cases, control circuitry monitors the temperature within the system and activates a control valve when a temperature threshold is met. Once the threshold temperature is reached, the CO₂ is exhausted from the canister into a lower pressure atmosphere for a period of time. The large drop in pressure results in a sharp drop in exhaust gas temperature which cools the heatsink. In some cases, circuit cards attached to the heatsink benefit from the conductive cooling of the CO₂ canister/heatsink assembly.

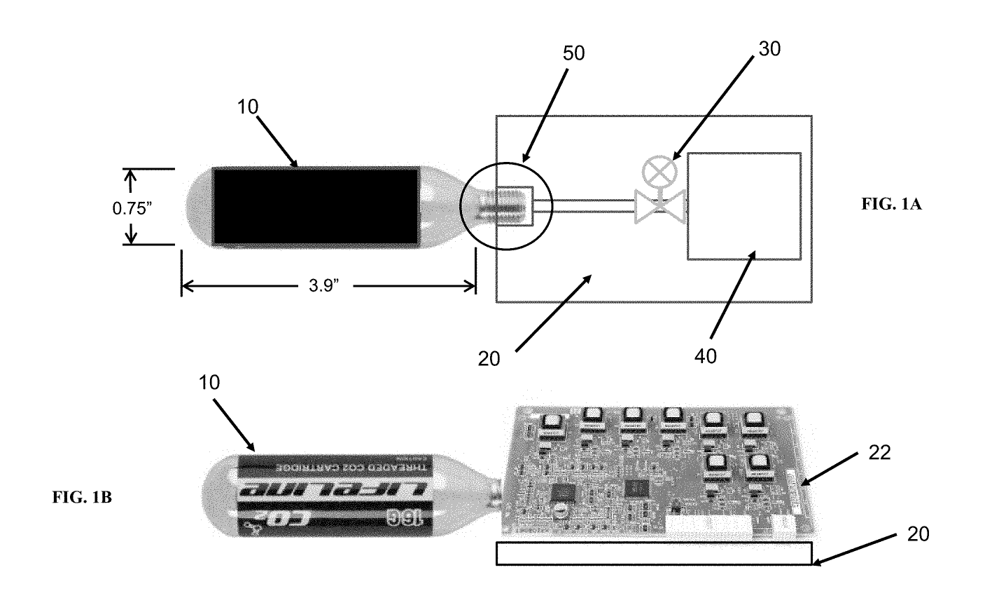

Referring to FIG. 1A, a diagram of one embodiment of the system of the present disclosure is shown. More specifically, a replaceable CO₂ cartridge 10 is shown connected to a heat sink 20. The heat sink may be in thermal contact with a circuit card assembly (CCA) or the like. As used herein, the thermal contact can be direct contact or indirect contact. For example, the heat sink may lower the temperature of the circuit card assembly directly but also indirectly lower the temperature of one or more components. In both cases the heat sink is in thermal contact with the circuit card and the component. In one embodiment of the system, the compressed gas cartridge 10 is attached via a connector interface 50 to the heat sink system such that the system can controllably release the contents of the compressed gas canister as needed for the particular application. The connector can be threaded, snap on or similar. In one embodiment, a metering valve 30 such as a regulator, provides for the controlled release of the compressed gas. The metering valve 30 can be manual or electronic. In one example the compressed gas enters into an expansion chamber 40 that can be coupled or integrated into the heat sink 20 and provide for conductive cooling of the heat sink 20. The expansion chamber 40 provides a mechanism for the cold gas to be stored and can be sized and located according to the application. For example, the expansion chamber 40 can be situated in proximity to the hot region of the circuit card 22 such that the conductive cooling from the heat sink is optimized. In a further example the expansion chamber is a series of channels in the heat sink 20 such that the compressed gas circulates through the heat sink. The size and density of the channels may be formed according to the design criteria. In one example, the heat sink would be manufactured by additive manufacturing. The chamber in one example has a relief valve that allows the compresses gas to escape upon reaching a certain pressure level. It is understood that upon expansion a cooling effect is generated in the expansion chamber 40 and that cooling effect is transferred to the heat sink 20. In another embodiment, the compressed gas may be vented to the atmosphere and not into an expansion chamber depending on the particular application. The venting into the chamber housing of the electronics would lower the chamber temperature and have some effect on the thermal characteristics.

Referring to FIG. 1B, a diagrammatic view of one embodiment of the system of the present disclosure is shown. More specifically, a circuit card assembly (CCA) 22 is connected to a heat sink 20 which is connected to a replaceable compressed gas cartridge 10. In some embodiments, the connection is similar in characteristics to a CO₂ bicycle tire inflator. As the gas escapes the pressurized vessel the gas becomes extremely cold. In one embodiment, a metering valve or regulator is placed in the cooling path. The result is that the heatsink becomes part of the compressed gas system. When the metering valve is open, the entire heatsink will drop in temperature. In certain embodiments, control circuitry opens the valve as temperatures approach component max junction temperatures or at a preset threshold temperature. This concept generally applies to short duration missions or as a means to mitigate against edge of the envelope requirements. In some cases, the CO₂ cartridge(s) can be replaced at the beginning of each mission.

In certain embodiments, more than one cartridge can be used in series. In one embodiment of the system of the present disclosure, a pair of compressed gas canisters is used. Depending on the cooling requirements of a particular electronic system, multiple compressed gas cartridges can be used in series and attached to a single heat sink. In cases where there are multiple, or even larger canisters, the cooling duration can be extended.

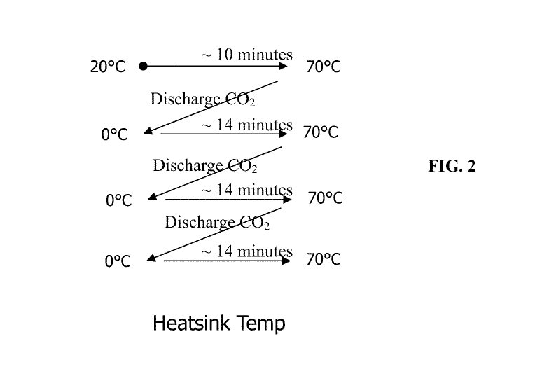

Referring to FIG. 2, a diagram of one embodiment of the method of the present disclosure is shown. More specifically, calculations using P₁V₁/T₁=P₂V₂/T₂ show that totally discharging a 12 gm CO₂ cartridge into a heatsink volume of 43 in³ results in a −110° C. gas temperature that will be absorbed by the heatsink walls/electronics. By using the metering valve to partially discharge the CO₂ cartridge at regular temperature intervals, for example, when the heatsink reaches 70° C., the electronics may be cooled for a period of time until the cycle repeats itself. In one embodiment it takes about four cycles to maintain a cooling state for a 60 minute duration using two compressed gas cartridges. In one embodiment, it can take about 10 minutes for the component's heat sink to reach 70° C. A first discharge of compressed gas results in the heatsink reaching a temperature of 0° C. Then, in can take about 14 minutes to reach the threshold temperature of 70° C. again. A second release of compressed gas results in the heatsink reaching a temperature of 0° C. Then, in can take about 14 minutes to reach the threshold temperature of 70° C. for the third time. A third release of compressed gas results in the heatsink reaching a temperature of 0° C. Then, in can take about 14 minutes to reach the threshold temperature of 70° C. for the fourth time. In one case, the system consumed two compressed gas cartridges and provided an hour of cooling in the field. It is understood that depending on power, ambient temperature, the size and number of canisters, and the like, the system can be customized for a variety of different applications as well as a variety of different missions.

In one embodiment, the system was implemented on a particular product with aggressive thermal environments. It was determined that a cooling system consisting of two CO₂ canisters would effectively cool a 75 W system at temperatures above 70° C. for a duration of 60 minutes. This represents an 80% improvement in mission duration over the baseline cooling concept where a fixed thermal mass was utilized to increase cooling capacitance. In theory, system weight could also be reduced because cooling capacity is not directly tied to the thermal mass of the system.

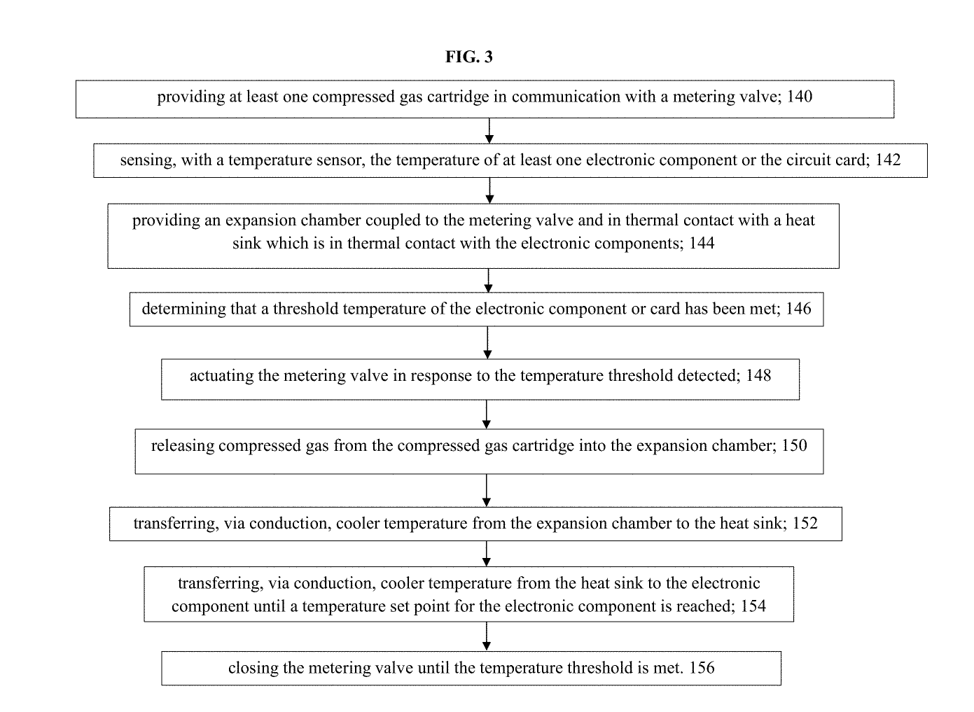

Referring to FIG. 3, a flowchart of one embodiment of the method of the present disclosure is shown. More specifically, at least one compressed gas cartridge in communication with a metering valve is provided 140. At least one temperature sensor senses the temperature of at least one electronic component, the circuit card or the proximity such as the housing 142. There are various types of temperature sensors that can be deployed on the circuit card, heat sink, housing or even proximate the components where the temperature is measured by infrared sensing. An expansion chamber in fluid connection with the metering valve and in thermal contact with a heat sink is provided, wherein the heat sink is in thermal contact with the circuit cards and electronic components 144. In one example, a threshold temperature is monitored and when met 146, the metering valve is actuated, such as via a controller, in response to the temperature threshold detected by the temperature sensor 148.

Still referring to FIG. 3, compressed gas is released from the compressed gas cartridge into the expansion chamber 150. In one example it is controllably released and can be stopped and started via the metering valve. Cooler temperature from the expansion chamber is transferred via conduction to the heat sink 152. Cooler temperature from the heat sink is transferred via conduction to the circuit card and electronic components until a temperature set point is reached 154. The electronic metering valve is then closed until the temperature threshold is met and the cycle continues 156.

In one embodiment of the system, the CO₂ cooling system is roughly 6″ wide by 14″ long by 1″ tall. It consists of an aluminum cold plate, or heatsink, with the aforementioned dimensions, 2 CO₂ canisters, a circuit card assembly, and a miniature control valve. In some cases, the CO₂ canisters are threaded into the aluminum cold plate and provide the active cooling “charge”. In certain embodiments, the aluminum cold plate has internal coolant passages that routes exhausted CO₂ throughout the system such that, when activated, the extreme pressure drop coupled with the velocity of escaping CO₂ gas will reduce the overall cold plate temperature.

In some embodiments, the circuit card assembly monitors the cold plate temperature and provides the control feedback mechanism for the exhaust valve. In some cases, when the temperature reaches a 70° C. threshold, it will open the exhaust valve until the temperature reaches the lower limit. In certain embodiments, there is no expansion chamber; the CO₂ is exhausted to atmosphere. Since CO2 is an inert gas, it poses no risk of damage to the electronics or surrounding platform.

In one embodiment of the system, the electronic subassembly is attached to the cooling system via fasteners that thread directly into the cold plate, or heat sink. The heat is conductively transferred from the electronics subassembly into the CO₂ cooled cold plate. In certain embodiments, the system allows the electronic subassembly to operate at temperatures above 70° C. for about 60 minutes by partially discharging the CO₂ at regular temperature intervals. In one example, the electronic subassembly dissipates a total of 75 W. If the 70° C. threshold is never met, then the system will not turn on, but will remain ready for the next excursion. To recharge the cooling system before each use, the CO₂ canisters could be removed and replaced with fresh ones. Additionally, an inherent advantage of this system is that as altitude increases, the pressure differential between the compressed CO₂ inside the canisters and the atmosphere also increases. This results in improved cooling efficiency at higher altitudes.

It is to be understood that the present invention can be implemented in various forms of hardware, software, firmware, special purpose processes, or a combination thereof. In one embodiment, the present invention can be implemented in software as an application program tangible embodied on a computer readable program storage device. The application program can be uploaded to, and executed by, a machine comprising any suitable architecture.

While various embodiments of the present invention have been described in detail, it is apparent that various modifications and alterations of those embodiments will occur to and be readily apparent to those skilled in the art. However, it is to be expressly understood that such modifications and alterations are within the scope and spirit of the present invention, as set forth in the appended claims. Further, the invention(s) described herein is capable of other embodiments and of being practiced or of being carried out in various other related ways. In addition, it is to be understood that the phraseology and terminology used herein is for the purpose of description and should not be regarded as limiting. The use of “including,” “comprising,” or “having,” and variations thereof herein, is meant to encompass the items listed thereafter and equivalents thereof as well as additional items while only the terms “consisting of” and “consisting only of” are to be construed in a limitative sense.

The foregoing description of the embodiments of the present disclosure has been presented for the purposes of illustration and description. It is not intended to be exhaustive or to limit the present disclosure to the precise form disclosed. Many modifications and variations are possible in light of this disclosure. It is intended that the scope of the present disclosure be limited not by this detailed description, but rather by the claims appended hereto.

A number of implementations have been described. Nevertheless, it will be understood that various modifications may be made without departing from the scope of the disclosure. Although operations are depicted in the drawings in a particular order, this should not be understood as requiring that such operations be performed in the particular order shown or in sequential order, or that all illustrated operations be performed, to achieve desirable results.

While the principles of the disclosure have been described herein, it is to be understood by those skilled in the art that this description is made only by way of example and not as a limitation as to the scope of the disclosure. Other embodiments are contemplated within the scope of the present disclosure in addition to the exemplary embodiments shown and described herein. Modifications and substitutions by one of ordinary skill in the art are considered to be within the scope of the present disclosure.

What is claimed:

1. A compressed gas cooling system, comprising:
at least one compressed gas cartridge having a connector end;
a metering valve connected to the at least one compressed gas cartridge via a connector interface;
a controller for actuating the metering valve in response to temperature threshold information from at least one temperature sensor;
an expansion chamber in fluid connection with the metering valve; and
a heat sink in thermal contact with an electronic component.

2. The compressed gas cooling system of claim 1, wherein the compressed gas cartridge is carbon dioxide.

3. The compressed gas cooling system of claim 1, wherein the at least one compressed gas cartridge is two cartridges.

4. The compressed gas cooling system of claim 1, wherein the heat sink comprises aluminum.

5. The compressed gas cooling system of claim 1, wherein a connector interface acts is a threaded connection for the at least one compressed gas cartridge.

6. The compressed gas cooling system of claim 1, further comprising a metering valve actuated via the at least one temperature sensor.

7. A method of cooling electronics, comprising:
providing at least one compressed gas cartridge in communication with a metering valve;
sensing, with a temperature sensor, the temperature of at least one electronic component;
providing an expansion chamber coupled to the metering valve and in thermal contact with a heat sink which is in thermal contact with the electronic component;
determining that a threshold temperature of the heat sink has been met;
actuating the metering valve in response to the temperature threshold;
releasing compressed gas from the compressed gas cartridge into the expansion chamber and producing a lower temperature expansion chamber;
conducting a temperature transfer from the lower temperature expansion chamber to the heat sink producing a lower temperature heat sink;
conducting a temperature transfer from the lower temperature heat sink to at least one electronic component.

8. The method of electronic cooling of claim 7, wherein the compressed gas cartridge is carbon dioxide.

9. The method of cooling of claim 7, further comprising opening and closing the metering valve based on the temperature threshold.

10. The method of cooling of claim 7, wherein the temperature threshold is 70° C.

11. The method of cooling of claim 7, wherein the temperature set point is 0° C.

12. The method of cooling of claim 7, wherein the period of time is between 10 minutes and 15 minutes.

13. The method of cooling of claim 7, wherein the heat sink comprises aluminum.

14. The method of cooling of claim 7, wherein a threaded interface acts as a connection for the at least one compressed gas cartridge.

15. The method of cooling of claim 7, wherein the metering valve is actuated via temperature sensing circuitry.

16. A compressed gas cooling system, comprising:
at least one compressed gas cartridge having a connector end;
a metering valve connected to the at least one compressed gas cartridge via a connector interface;
a controller for actuating the metering valve in response to temperature threshold information from at least one temperature sensor; and
an aluminum heat sink having internal coolant passages that routes exhausted compressed gas from the gas cartridge, wherein the heat sink is in thermal contact with at least one electronic component.

17. The compressed gas electronic cooling system of claim 16, wherein the compressed gas cartridge is carbon dioxide.

18. The compressed gas electronic cooling system of claim 16, wherein the at least one compressed gas cartridge is two cartridges.

19. The compressed gas electronic cooling system of claim 16, wherein a threaded interface acts as the connector for the at least one compressed gas cartridge.

20. The compressed gas electronic cooling system of claim 16, wherein the metering valve is actuated via temperature sensing circuitry.
